(19) United States
(12) Patent Application Publication
(10) Pub. No.: US 2019/0190237 A1
(43) Pub. Date: Jun. 20, 2019

(54) OPTICAL FREE AIR BUS INTERCONNECT

(71) Applicant: Intel Corporation, Santa Clara, CA (US)

(72) Inventors: Arvind Sundaram, Bangalore (IN); Ajay V. Bhatt, Portland, OR (US)

(21) Appl. No.: 16/328,121

(22) PCT Filed: Sep. 29, 2016
(86) PCT No.: PCT/US2016/054365

§ 371 Date: Feb. 25, 2019

(51) Int. Cl. H01S 5/40; G02B 6/293; H01S 5/00

(52) U.S. Cl. CPC H01S 5/4087; H01S 5/005; G02B 6/293

(57) ABSTRACT

An apparatus comprises a plurality of laser emitters each having a different center frequency; a plurality of photodiodes arranged to receive laser energy from the laser emitters via an air space; and a plurality of laser bandpass filters arranged between the plurality of laser emitters and the plurality of photodiodes, wherein each one of the photodiodes is arranged to receive laser energy respectively via one of the laser bandpass filters, and wherein each laser bandpass filter has one of the different center frequencies included in a passband of the laser bandpass filter and has the other of the different center frequencies excluded from the passband.

### TECHNICAL FIELD

Embodiments pertain to high speed interconnections in electronic systems, and more specifically to optical communication interfaces between electronic devices.

### BACKGROUND

Electronic systems often include electronic devices that communicate signals to each other. Designers of electronic systems strive to increase the speed of the communication among devices while keeping the communication link robust. Wireless connections can be more robust than wired connections because of the elimination of the need for mechanical contact that may be susceptible to wear. Wireless interfaces typically communicate using radio frequency (RF) signals. However, some limitations of RF communication interfaces include bandwidth limitations, signal interference, and overhead associated with RF protocols. Optical signals can be an alternative to RF and can achieve higher data rates. However, traditional optical interconnects require special fiber-optic cables, which can be more expensive than wired interfaces, and can require air tight glass-to-glass connections to prevent Fresnel reflections, making them less desirable and, in certain examples, impractical for day-to-day free-air interconnects. There is a general need for devices, systems and methods to address requirements for high-speed interconnections among electronic devices.

### BRIEF DESCRIPTION OF THE DRAWINGS

FIG. 1 is an illustration of an optical transmitter (TX) receiver (RX) pair in accordance with some embodiments;

FIG. 2 is an illustration of another optical TX/RX pair in accordance with some embodiments;

FIG. 3 is an illustration of portions of an optical interface in accordance with some embodiments;

FIG. 4 is an example of a filter characteristic for a laser bandpass filter in accordance with some embodiments;

FIG. 5 is a flow diagram of a method of forming multiple optical receivers in accordance with some embodiments;

FIG. 6 is an illustration of portions of a process to coat lenses for multiple optical receivers in accordance with some embodiments;

FIG. 7 is an illustration of embodiments of a rotary mask, planetary gear mechanism, and a target carrier of an IBS process in accordance with some embodiments;

FIG. 8 is a block diagram of an example of an electronic system in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

There are many types of communication interfaces between electronic devices. These include universal serial bus (USB), mobile industry processor interface (MIPI), peripheral component interconnect (PCI), PCI express (PCIe), high definition multimedia interface (HDMI), thunderbolt (TBT), display port (DP) interface, and other serial busses and serial-parallel busses used in consumer electronics, enterprise class devices, wearable electronic devices, portable computers, and tablet computers. It is desirable to implement a wireless communication interface that can provide improved data rate and can adapt basic wireless interconnection with all of the protocols available and yet not be tied to any one specific protocol. An infrared-based interface is an alternative to an RF interface, but an IR-based interface involves conversion between protocols, which adds overhead to the communication. A laser-based optical interface would meet these requirements for the interconnection, but the cost of fiber optic based optical interconnections can be prohibitive.

A better option is a laser-based optical interface that does not use fiber optics to transmit and receive the laser emitted signals, but instead transmits the optical signals via free air space (e.g., a light amplitude modulation docking adapter, or LAMDA). This can be accomplished by communicating the optical signals over short distances in air (e.g., about ten millimeters (10mm)) so that signal loss is tolerable. The free air optical interface can scale to data rates up to ten gigabits per second (10 Gbps) and rates of one terabit per second (1 Tbps) may be available. This type of optical interface is not tied to any specific protocol and eliminates protocol overhead, which reduces the latency in communication to near zero latency. Further, the interface is agnostic to clock rate, making the interface compatible with high speed and low speed interfaces. It would be desirable for a free air optical interface to provide some degree of parallelism in the transfer of data. This would increase data rate and also would allow for data transfer via the optical interface that follows a standard interface communication protocol.

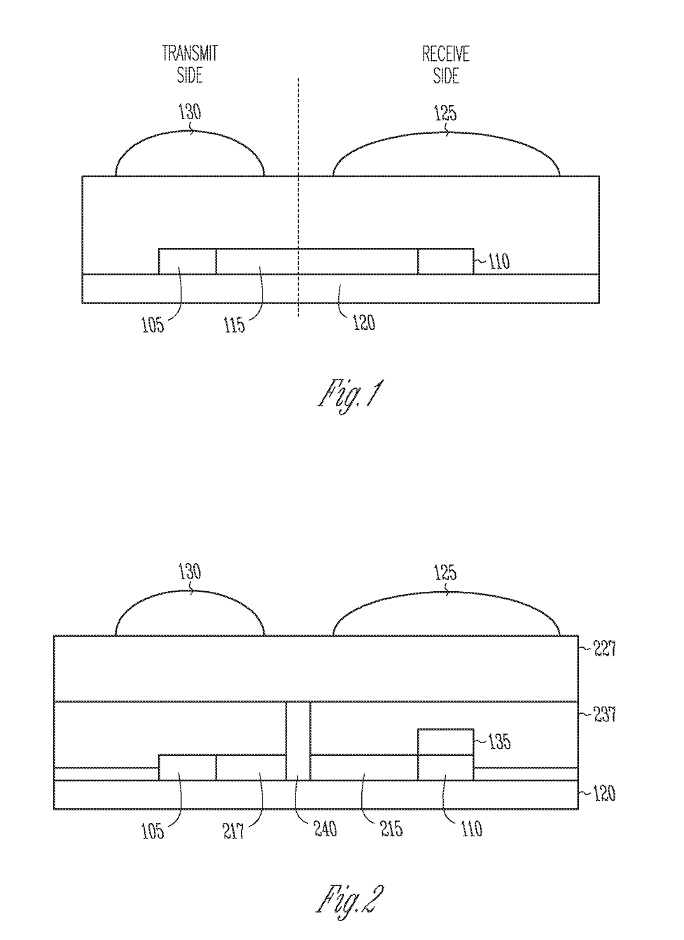

FIG. 1 is an illustration of an embodiment of an optical transmitter (TX) receiver (RX) pair. The optical TX/RX pair can include a laser emitter 105, such as a laser diode or a vertical-cavity surface emitting laser (VCSEL) for example. The optical receiver can include a photodiode 110 to convert received laser energy into an electrical signal. A trans-impedance amplifier 115 (TIA) can be included to amplify the electrical signal generated by the photodiode. The laser emitter 105 and the photodiode 110 are arranged on a substrate 120. Some examples of the substrate 120 include a printed circuit board (PCB) made of plastic or ceramic. To form a serial optical interface, a second optical TX/RX pair can be positioned opposite the optical TX/RX pair in

FIG. 1. The two TX/RX pairs are separated by an air gap. The emitter of the second optical TX/RX pair is arranged opposite the optical receiver of the first optical TX/RX pair to create a first communication lane, and the emitter of the first optical TX/RX pair is arranged opposite the optical receiver of the second TX/RX pair to form a second communication lane in the reverse direction from the first communication lane. The TX/RX pair can include a lens 125 to focus incident laser energy onto the photodiode 110. The TX/RX pair may also include a second lens 130 to focus the emitted laser energy toward the receiving photodiode across the air gap.

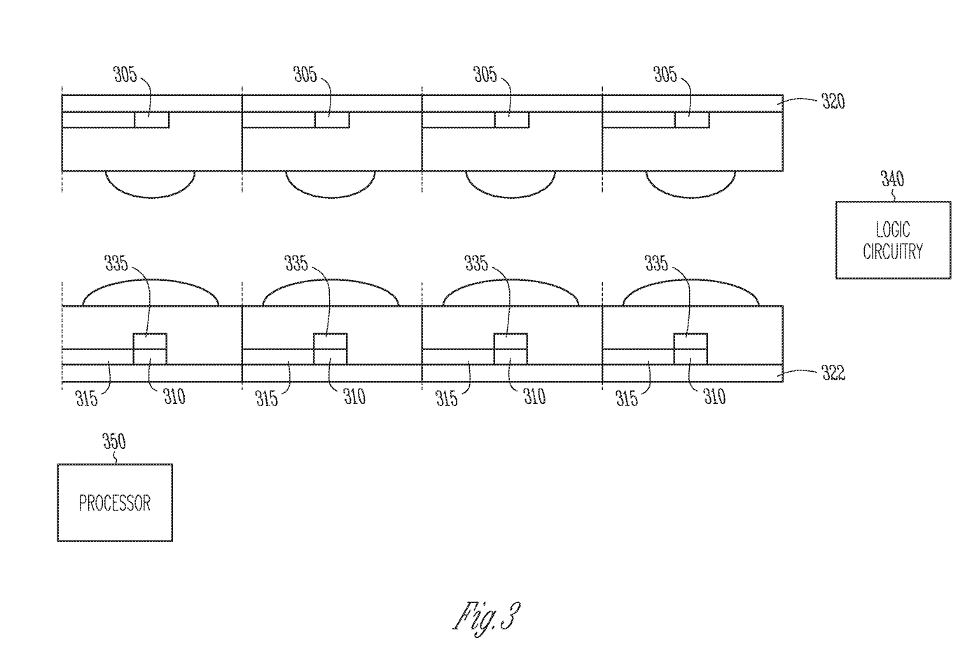

FIG. 2 is an illustration of another embodiment of an optical transmitter TX/RX pair. A trans-impedance amplifier 215 (TIA) can be used to amplify the electrical signal generated by the photodiode 110. A drive amplifier 217 may also be included to translate signals to be transmitted to levels of power or voltage needed to drive the laser emitter 105. A resin 237 may be disposed on the substrate to encapsulate the electronics. The resin may be an optically clear resin (OCR) that flows before hardening. However, OCR may be susceptible to scratching. Because the optical interface is exposed to air rather than being protected using connections to fiber-optics, the optical TX/RX pair may need a surface with a higher degree of hardness than a resin can provide.

The optical TX/RX pair includes a lens 227. The lens may have a surface hardness rating of 8H or higher. The lens 227 can include a first lens portion 125 having a first curvature arranged above the photodiode 110 and a second lens portion 130 having a second curvature arranged above the laser emitter 105. The example in FIG. 2 shows a laser bandpass filter 135 arranged above the photodiode 110. The purpose of the laser bandpass filter 135 is explained below. The lens 227 may be pre-formed prior to assembly and may include alumina silicate glass or a co-polymer coated poly(methyl methacrylate) (PMMA), such as sol-gel coated PMMA for example The lens may have the same refractive index as the OCR to prevent reflections at the OCR/lens interface. The lens may also provide protection from humidity. An isolation barrier 240 may be arranged on the substrate between the laser emitter and the photodiode. The isolation barrier 240 may extend from the substrate to the top surface of the resin and may also serve as a support for the lens during curing of the resin.

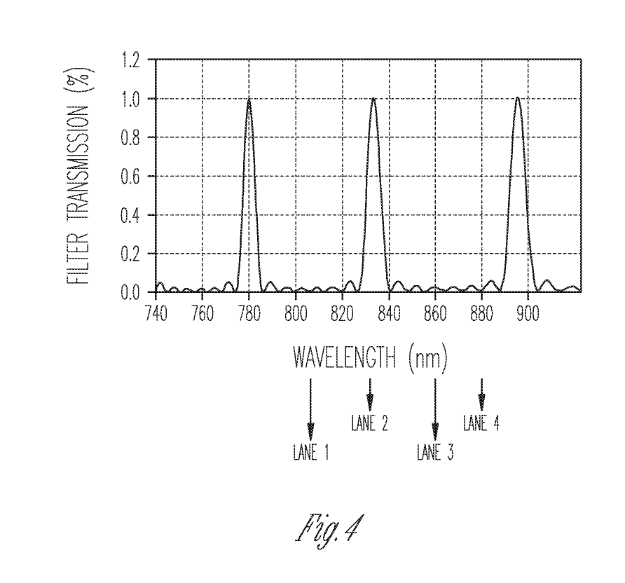

A higher bandwidth interface can be formed using multiple communication lanes. Data can then be communicated in parallel using the multiple communication lanes. FIG. 3 is an illustration of portions of an embodiment of an optical interface. To provide parallelism for the interface, multiple laser emitters 305 are paired with multiple photodiodes 310 to form multiple communication lanes. Four communication lanes are shown in the example embodiment of FIG. 3, but other numbers of communication lanes can be formed (e.g., two communication lanes, or eight communication lanes). The laser emitters can be arranged on a first substrate 320 and the photodiodes can be arranged on a second substrate 322. TIAs 315 may be electrically coupled to the photodiodes 310 and included on the second substrate 322. An air gap separates the four emitter-photodiode (TX/RX) pairs. The separation between the two optical TX/RX pairs is small (e.g., about 2.5 mm). The small separation allows for the photodiode receivers to reliably detect the laser energy from the emitters.

The communication lanes of the optical interfaces may be parallel data lines of an optical bus interface. The optical interface example in FIG. 3 communicates data from the four laser emitters to the four photodiodes. An electronic device may include four laser emitters in one optical interface and include four photodiodes in a second optical interface to provide parallel transfer of data in both directions.

To keep the size of the optical interconnection small, the laser emitters and the photodiodes may be included in the same electronics package. In other embodiments, the substrates 320, 322 are electronic package substrates and the laser emitters are included in a first electronics package and the photodiodes are included in a second electronics package. In some embodiments, the laser emitters and the photodiodes are included in a single mechanical connector. The mechanical connector can include a first connector body portion that includes the electronic package containing the laser emitters and a second connector body portion that includes the electronic package containing the photodiodes. Joining the connector body portions forms a housing to protect against interference from outside sources. However, it may be desirable to use a type of photodiode in the interface that has a wide spectral response to detect laser energy transmitted over the air gap. The wide spectral response can create crosstalk between the communication lanes if one photodiode detects laser energy from more than one laser emitter.

To reduce or eliminate crosstalk between communication lanes, each laser emitter 305 emits laser energy using a different specified center frequency. Each photodiode of each communication lane includes a laser bandpass filter 335 arranged above the photodiode 310. Some examples of a laser bandpass filter include a Lyot filter or a dichroic filter. A laser bandpass filter may a lens positioned above the photodiode. Each laser bandpass filter 335 has a passband that includes the center frequency of the laser energy emitted by the laser emitter of the communication lane, but excludes the center frequency of the laser energy emitted by the laser emitters of the other communication lanes. The result is that all four communication lanes can transact data without interference.

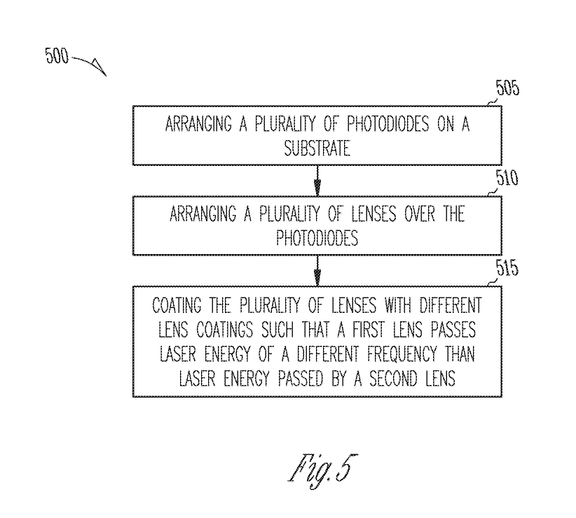

FIG. 4 is an example of a filter characteristic for the laser bandpass filter of communication lane 2. The example is intended to be illustrative and non-limiting. The filter characteristic shows filter transmission versus wavelength in nanometers (nm). In the example, the laser emitter of communication lane 1 emits laser energy with a wavelength of 808 nm, the laser emitter of communication lane 2 emits laser energy with a wavelength of 830 nm, the laser emitter of communication lane 3 emits laser energy with a wavelength of 855 nm, and the laser emitter of communication lane 4 emits laser energy with a wavelength of 880 nm. The filter characteristic for communication lane 2 shows that the passband of the laser bandpass filter includes the 830 nm laser energy of lane 2 and shows very high attenuation for the laser energy emitted by the other communication lanes. Thus, the laser bandpass filter reduces or eliminates the laser energy from other communication lanes being detected.

Returning to FIG. 3, the communication lanes may be electrically coupled to logic circuitry 340 that transmits and receives signals communicated according to a parallel bus interface protocol via the optical interface. The bus protocol may be, among other things, a USB protocol, an MIPI protocol, a PCI or PCIe protocol, an HDMI protocol, a TBT interface protocol, or a DP interface protocol. The logic circuitry may be included in the electronics package as the laser emitters and photodiodes. In some embodiments, the logic circuitry is included on one or both of the substrates 320, 322. A processor 350 may then communicate data according to the bus protocol. The optical interface may be transparent to the processor 350 and the communication appears to be a standard communication interface to client applications executing on the processor 350.

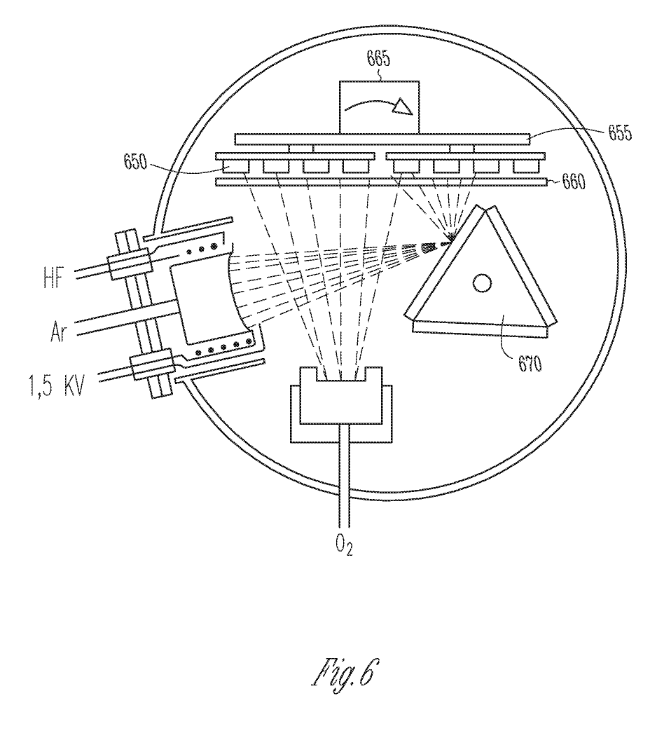

FIG. 5 is a flow diagram of an embodiment of a method 500 of forming multiple optical receivers. At 505, multiple photodiodes are arranged on a substrate. The photodiodes may be a type of photodiode that has a wide spectral response (e.g., an indium gallium arsenide (InGaAs) photodiode). The substrate may be a printed circuit board (PCB) and the photodiodes may be mounted on the top side of the PCB, and the PCB may include solder pads on the bottom side. In certain embodiments the substrate is ceramic, and in certain embodiments the substrate is plastic. A TIA may be arranged on the substrate with each of the photodiodes.

At 510, a lens is arranged over each of the photodiodes. In some embodiments, the lenses are formed over the photodiodes using an epoxy molding process. The lens may include a curvature that focuses incident laser energy onto the photodiode.

At 515, the lenses are coated with different lens coatings to form laser bandpass filters. In some embodiments, the lenses are coated using a thin film ion beam sputtering (IBS) process. The lenses may be coated by IBS using a mask that includes openings of different specified sizes to apply different coatings to the lenses. A coating applied to a first lens is different from a coating applied to a second lens, so that the first lens passes laser energy of a different frequency than laser energy passed by the second lens. After the coating is applied, each of the lenses may include a passband different from the passband of the other lenses.

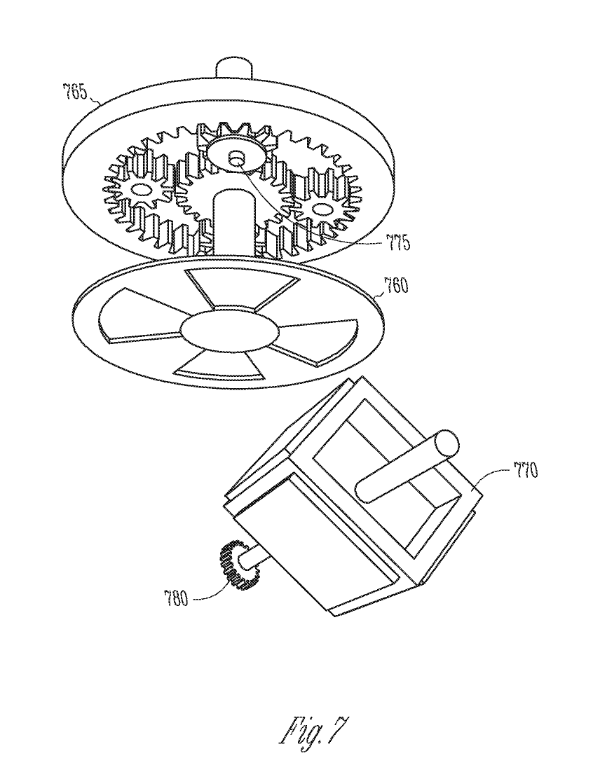

FIG. 6 is an illustration of portions of an embodiment of a process to coat lenses for multiple optical receivers. Multiple substrates 650 are arranged on a substrate tray 655. Each of the substrates includes multiple lenses to be coated using an IBS process. In the example embodiment shown four lenses are arranged on a substrate 650 or lens platter. A mask 660 is used in coating the lenses, and the mask is moved in a fixed relationship to the substrate tray passed an IBS source. In some embodiments, the substrate tray is rotated passed the IBS source using a planetary gear 665. The mask 660 may be a rotary mask that is moved in a fixed gear ratio with the planetary gear. The rotary mask may be part of the planetary gear mechanism. The mask includes different sized openings or cut outs at different lens positions. A portion of each lens is exposed to the IBS and the rest of the lens is shielded by the mask. As the substrate tray 655 rotates and revolves, so does the mask 660 in a fixed gear motion with the substrate tray. The rotation of the mask and substrate tray may be tied to rotation of the IBS targets on the target carrier 670 as well. The different sized openings in the mask cause different lens coatings to be formed on the lenses to create different filtering properties. In some embodiments, Lyot filters are formed on the lenses using the IBS process. In some embodiments, dichroic filters are formed on the lenses.

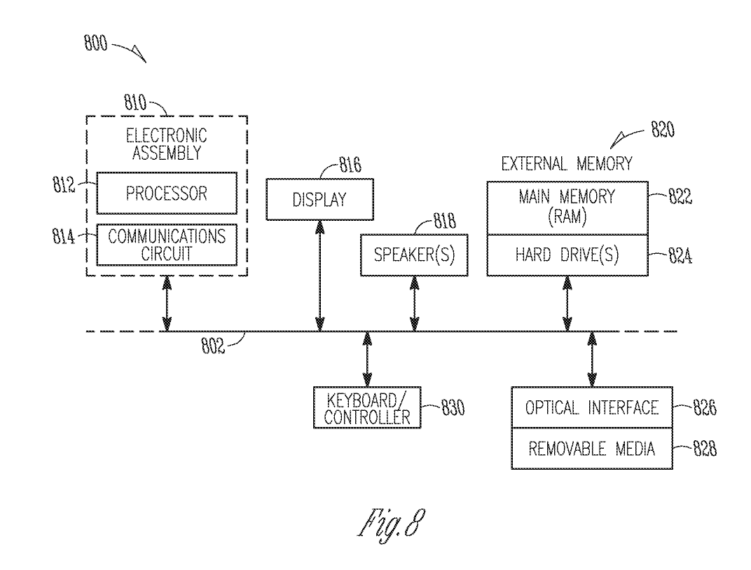

FIG. 7 is an illustration of embodiments of a rotary mask 760, planetary gear mechanism 765, and a target carrier 770 of an IBS process. Planet wheels 775 of the planetary gear mechanism 765 move the lenses on the lens substrates. Non-linear gears may be used in the planetary gear mechanism to produce a different coating thickness for different lenses. The rotary mask 760 shows four cut outs for coating the lenses arranged on the substrate 750 of FIG. 6. Each lens of a substrate will be coated with a different laser bandpass filter. The target carrier 770 may be connected by one or more slot or cam gears 780 to the planetary gear mechanism 765. IBS targets of the target carrier 770 may be rotated at specified intervals rather than a continuous motion. Four different IBS targets are shown on the IBS carrier. Each target may deposit a layer of Lyot coating that determines the passband of the laser bandpass filter.

When the optical receivers are formed they may be paired with laser emitters in an electronics package and separated from the laser emitters by an air space to form optical communication lanes. The photodiodes, TIAs and laser bandpass filters receive laser energy from the laser emitters via the air space to communicate data. The bandpass filters of the lenses reduce or prevent crosstalk between the communication lanes. The communication lanes provide a robust and high speed parallel communication link that is agnostic to clock rate and communication protocol.

The free air optical interface can be included in a personal computer (PC) or a mobile computing device such as a smart phone, tablet, compute stick, etc. The optical interface can be used to connect peripheral devices to the PC or mobile computing device. The optical interface can be included in a server, mini-server, or micro-server, and can be used for agnostic backplane connections to servers.

FIG. 8 is a block diagram of an example of an electronic system 800 incorporating at least one electronic circuit assembly and in accordance with at least one embodiment of the invention. Electronic system 800 is merely one example in which embodiments of the present invention can be used. Examples of electronic systems 800 include, but are not limited to personal computers, tablet computers, mobile telephones, game devices, compute sticks etc. In this example, electronic system 800 comprises a data processing system that includes a system bus 802 to couple the various components of the system. System bus 802 provides communications links among the various components of the electronic system 800 and can be implemented as a single bus, as a combination of busses, or in any other suitable manner

An electronic assembly 810 can be coupled to system bus 802. The electronic assembly 810 can include any circuit or combination of circuits.

In one embodiment, the electronic assembly 810 includes a processor 812 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 810 are a custom circuit, an application-specific integrated circuit (ASIC), or the like. The electronic assembly can include a communications circuit 814 for use in wireless devices like mobile telephones, personal data assistants, portable computers, two-way radios, and similar electronic systems.

The electronic system 800 can also include an external memory 820, which in turn can include one or more memory elements suitable to the particular application, such as a main memory 822 in the form of random access memory (RAM), one or more hard drives 824. The electronic assembly 810 can also include a free air optical interface 826 for removable media 828 such as compact disks (CD), flash memory cards, digital video disk (DVD), and the like.

The electronic system 800 can also include a display device 816, one or more speakers 818, and a keyboard and/or controller 830, which can include a mouse, trackball, touch screen, voice-recognition device, or any other device that permits a system user to input information into and receive information from the electronic system 800.

### ADDITIONAL DESCRIPTION AND EXAMPLES

Example 1 includes subject matter (such as an apparatus) comprising: a plurality of laser emitters each having a different center frequency; a plurality of photodiodes arranged to receive laser energy from the laser emitters via an air space; and a plurality of laser bandpass filters arranged between the plurality of laser emitters and the plurality of photodiodes, wherein each one of the photodiodes is arranged to receive laser energy respectively via one of the laser bandpass filters, and wherein each laser bandpass filter has one of the different center frequencies included in a passband of the laser bandpass filter and has the other of the different center frequencies excluded from the passband.

In Example 2, the subject matter of Example 1 optionally includes an electronics package that includes a package substrate, and wherein the plurality of laser emitters are arranged on the package substrate.

In Example 3, the subject matter of one or both of Examples 1 and 2 optionally includes four laser emitters and the plurality of photodiodes includes four photodiodes.

In Example 4, the subject matter of one or any combination of Examples 1-3 optionally includes a plurality of trans-impedance amplifiers (TIAs) electrically coupled to the photodiodes, wherein the TIAs and the photodiodes are arranged on a substrate and a laser emitter is paired with a photodiode and a TIA as one communication lane.

In Example 5, the subject matter of one or any combination of Examples 1-4 optionally includes a plurality of vertical-cavity surface emitting lasers (VCSELs).

In Example 6, the subject matter of one or any combination of Examples 1-5 optionally includes a plurality of laser bandpass filters that includes a plurality of Lyot filters.

In Example 7, the subject matter of one or any combination of Examples 1-6 optionally includes logic circuitry configured to communicate signals using the laser emitter and photodiodes according to a parallel bus interface communication protocol.

Example 8 can include subject matter (such as a method of forming optical receivers), or can optionally be combined with one or any combination of Example 1-7 to include such subject matter, comprising: arranging a plurality of photodiodes on a substrate; arranging a plurality of lenses over the photodiodes; and coating the plurality of lenses with different lens coatings such that a first lens passes laser energy of a different frequency than laser energy passed by a second lens.

In Example 9, the subject matter of Example 8 optionally lenses includes ion beam sputtering (IBS) of a thin film onto the plurality of lenses using a mask, wherein the mask includes openings of different specified sizes to apply a coating to the first lens that is different from a coating of the second lens.

In Example 10, the subject matter of Example 9 optionally includes arranging a plurality of substrates on a substrate tray; and moving the mask passed an IBS source in a fixed relationship to the substrate tray.

In Example 11, the subject matter of one or both of Examples 9 and 10 optionally includes rotating the substrate tray using a planetary gear, and wherein moving the mask includes moving a rotary mask in a fixed gear ratio with the planetary gear.

In Example 12, the subject matter of one or any combination of Examples 8-11 optionally includes coating the plurality of lenses to form a plurality of Lyot filters on the lenses.

In Example 13, the subject matter of one or any combination of Examples 8-12 optionally includes arranging a plurality of laser emitters in a same electronics package as the plurality of photodiodes, wherein the photodiodes are further arranged to receive laser energy from the laser emitters via an air space of the electronics package.

In Example 14, the subject matter of one or any combination of Examples 8-13 optionally includes: arranging four photodiodes and four trans-impedance amplifiers (TIAs) on the substrate, and arranging laser emitters with photodiode-TIA combinations to form an optical communication lane.

Example 15 can include subject matter (such as an apparatus), or can optionally be combined with one or any combination of Examples 1-14 to include such subject matter, comprising: a processor configured to communicate information using a bus protocol; and an optical bus interface electrically coupled to the processor and including: a plurality of laser emitters arranged on a first substrate, wherein laser energy emitted by each laser emitter has a different center frequency; a plurality of photodiodes arranged on a second substrate to receive laser energy from the laser emitters via an air space; a plurality of laser bandpass filters arranged between the plurality of laser emitters and the plurality of photodiodes, wherein each one of the photodiodes is arranged to receive laser energy respectively via one of the laser bandpass filters, and wherein each laser bandpass filter includes one of the different center frequencies in a passband of the laser bandpass filter and excludes the other of the different center frequencies from the passband; and logic circuitry configured to transmit and receive signals communicated according to a bus protocol via the optical bus interface, and wherein the plurality of laser emitters, the plurality of photodiodes, and the logic circuitry are included in the same electronics package.

In Example 16, the subject matter of Example 15 optionally includes logic circuitry configured to transmit and receive signals communicated via the optical bus interface according to a parallel bus interface protocol.

In Example 17, the subject matter of one or both of Examples 15 and 16 optionally includes an optical bus interface that includes a plurality of data lines.

In Example 18, the subject matter of one or any combination of Examples 15-17 optionally includes an electronics package that includes a package substrate and the plurality of laser emitters are arranged on the package substrate.

In Example 19, the subject matter of one or any combination of Examples 15-18 optionally includes a plurality of vertical-cavity surface emitting lasers (VCSELs).

In Example 20, the subject matter of one or any combination of Examples 15-19 optionally includes a plurality of laser bandpass filters includes a plurality of Lyot filters.

These several non-limiting Examples can be combined using any permutation or combination. The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

1.-20. (canceled)

21. An apparatus comprising:
a plurality of laser emitters each having a different center frequency;
a plurality of photodiodes arranged to receive laser energy from the laser emitters via an air space; and
a plurality of laser bandpass filters arranged between the plurality of laser emitters and the plurality of photodiodes, wherein each one of the photodiodes is arranged to receive laser energy respectively via one of the laser bandpass filters, and wherein each laser bandpass filter has one of the different center frequencies included in a passband of the laser bandpass filter and has the other of the different center frequencies excluded from the passband.

22. The apparatus of claim 21, including an electronics package that includes a package substrate, and wherein the plurality of laser emitters are arranged on the package substrate.

23. The apparatus of claim 22, wherein the plurality of laser emitters includes four laser emitters and the plurality of photodiodes includes four photodiodes.

24. The apparatus of claim 21, including a plurality of trans-impedance amplifiers (TIAs) electrically coupled to the photodiodes, wherein the TIAs and the photodiodes are arranged on a substrate and a laser emitter is paired with a photodiode and a TIA as one communication lane.

25. The apparatus of claim 21, wherein the plurality of laser emitters includes a plurality of vertical-cavity surface emitting lasers (VCSELs).

26. The apparatus of claim 21, wherein the plurality of laser bandpass filters includes a plurality of Lyot filters.

27. The apparatus of claim 21, including logic circuitry configured to communicate signals using the laser emitter and photodiodes according to a parallel bus interface communication protocol.

28. A method comprising:
arranging a plurality of photodiodes on a substrate;
arranging a plurality of lenses over the photodiodes; and
coating the plurality of lenses with different lens coatings such that a first lens passes laser energy of a different frequency than laser energy passed by a second lens.

29. The method of claim 28, wherein coating the plurality of lenses includes ion beam sputtering (IBS) of a thin film onto the plurality of lenses using a mask, wherein the mask includes openings of different specified sizes to apply a coating to the first lens that is different from a coating of the second lens.

30. The method of claim 29, including arranging a plurality of substrates on a substrate tray; and moving the mask passed an IBS source in a fixed relationship to the substrate tray.

31. The method of claim 29, including rotating the substrate tray using a planetary gear, and wherein moving the mask includes moving a rotary mask in a fixed gear ratio with the planetary gear.

32. The method of claim 28, wherein coating the plurality of lenses with different lens coatings includes coating the plurality of lenses to form a plurality of Lyot filters on the lenses.

33. The method of claim 28, including arranging a plurality of laser emitters in a same electronics package as the plurality of photodiodes, wherein the photodiodes are further arranged to receive laser energy from the laser emitters via an air space of the electronics package.

34. The method of claim 33, wherein arranging a plurality of photodiodes on a substrate includes: arranging four photodiodes and four trans-impedance amplifiers (TIAs) on the substrate, and arranging laser emitters with photodiode-TIA combinations to form an optical communication lane.

35. An apparatus comprising:
a processor configured to communicate information using a bus protocol; and
an optical bus interface electrically coupled to the processor and including:
a plurality of laser emitters arranged on a first substrate, wherein laser energy emitted by each laser emitter has a different center frequency;
a plurality of photodiodes arranged on a second substrate to receive laser energy from the laser emitters via an air space;
a plurality of laser bandpass filters arranged between the plurality of laser emitters and the plurality of photodiodes, wherein each one of the photodiodes is arranged to receive laser energy respectively via one of the laser bandpass filters, and wherein each laser bandpass filter includes one of the different center frequencies in a passband of the laser bandpass filter and excludes the other of the different center frequencies from the passband; and
logic circuitry configured to transmit and receive signals communicated according to a bus protocol via the optical bus interface, and wherein the plurality of laser emitters, the plurality of photodiodes, and the logic circuitry are included in the same electronics package.

36. The apparatus of claim 35, wherein the logic circuitry is configured to transmit and receive signals communicated via the optical bus interface according to a parallel bus interface protocol.

37. The apparatus of claim 35, wherein the optical bus interface includes a plurality of data lines.

38. The apparatus of claim 35, wherein the electronics package includes a package substrate and the plurality of laser emitters are arranged on the package substrate.

39. The apparatus of claim 35, wherein the plurality of laser emitters includes a plurality of vertical-cavity surface emitting lasers (VCSELs).

40. The apparatus of claim 35, wherein the plurality of laser bandpass filters includes a plurality of Lyot filters.
